(19) United States
(12) Patent Application Publication
(10) Pub. No.: US 2002/0035717 A1
(43) Pub. Date: Mar. 21, 2002

(54) Navigation method and device for pattern observation of semiconductor device

(76) Inventor: Ryoichi Matsuoka, Chiba-shi (JP)

Correspondence Address: ADAMS & WILKS, 31st Floor, 50 Broadway, New York, NY, 10004, US

(21) Appl. No.: 09/903,790

(22) Filed: Jul. 12, 2001

(30) Foreign Application Priority Data
Jul. 14, 2000 (JP) 2000-214846

(51) Int. Cl. G06F 17/50; H01L 21/00; H01L 21/66; G06F 9/45; G01R 31/26

(52) U.S. Cl. 716/4; 438/7; 438/14; 438/16; 716/5

(57) ABSTRACT

Low magnification factor pattern image data D1 including the center of the observational position is acquired by adjusting an observation position using a pattern observation device 3 so that the center of observation of prescribed locations of a pattern enter the observational field of view at a low magnification factor. Data D4 for an offset amount caused by errors for the stage 2 is obtained by comparing the edge line segment data D2 based on low magnification factor pattern image data D1 to corresponding CAD line segment data D3. The stage 2 is moved relatively to compensate the offset amount to align the observational field of view of the pattern observation device 3 precisely at the specified pattern portion.

### BACKGROUND OF THE INVENTION

1. Field of the Invention

The present invention relates to a navigation method and device for pattern observation for a semiconductor device.

2. Description of the Prior Art

In various semiconductor manufacturing processes, a wafer pattern observation device is used when the need arises to check whether or not a pattern on wafer has been formed as planned, or to check whether or not the formed pattern is defective. A wafer pattern observation device used for this type of purpose magnifies an observational subject pattern portion, within an area from a few to a few tens of μm square in a pattern formed on the wafer, to a high magnification factor and performs observation, which means that the observational field of view of the wafer pattern observation device must be positioned with high precision at a desired observational position on the wafer.

In the related art, so called CAD navigation is generally used as the navigation method pattern portion positioning, where the observation object is specified with a CAD device.

Recent improvement in semiconductor manufacturing technology has enabled wafer pattern formation of sub micron dimensions, and wafer pattern observation devices with a high magnification factor have come into use for observation of these ultra fine patterns. When observing a pattern at such a high magnification factor using the wafer pattern observation device, a problem occurs with regard to errors in positioning the stage on which the semiconductor device, as an observation object, is placed. This stage errors cause difficulties in the required highly precise observation point positioning using the CAD navigation method of the related art. As a result, there is a good possibility that a pattern portion, as an observation object, may be out of the observational field of view and observation at a high magnification factor becomes difficult. Furthermore, there is also a problem that the magnification factor cannot be controlled accurately.

To solve these problems, in a high magnification factor pattern observation, the observational field of view is positioned at the desired observational position on the wafer finally by adjusting the stage error manually even with a CAD navigation device, and so automation of the observation was not achieved. As a result, performance of the pattern observation is inefficient, and improvement in productivity has been prevented.

### SUMMARY OF THE INVENTION

It is an object of the present invention to provide a navigation method and a device for pattern observation of semiconductor device, where the observational position on the wafer pattern, observed with the wafer pattern observation device used in the semiconductor manufacturing processes, can be positioned with high precision without manual intervention.

To solve the above problems, according to the invention of claim 1, there is proposed a navigation method for magnifying a specified pattern portion of a semiconductor device set on a stage for observation to a high magnification factor, and for placing the observational field of view of the pattern observation device at the specified pattern portion of the semiconductor device, comprising the steps of performing observational positioning of the pattern observation device to a low magnification factor so that observation center of the specified portion is placed in an observational field of view to acquire the low magnification factor pattern image data, calculating an offset amount between the observation center and center of the observational field of view from the low magnification factor pattern image data and CAD graphics data corresponding to the low magnification factor pattern image data and performing positional control by compensating the stage error based on this offset amount data so that the center of observation is aligned with the center of the observational field of view.

The observation center of the specified portion in the image based on the low magnification factor pattern image data is offset from the center of the observational field of view of the pattern observation device because of stage error, in spite of observational positioning. The offset amount, which is the degree of offset, can be obtained by matching calculation using the corresponding CAD graphics data. By performing position control using the obtained offset amount, the observation center of the specified portion to be observed at a high magnification factor can be aligned with the center of the observational field of view. As a result, the pattern observation device can perform observational positioning precisely for the desired high magnification factor observation conditions, so that the specified portion is placed in an observational field of view, and the specified portion can be observed at the desired high magnification factor.

According to the invention of claim 2, a navigation method for pattern observation of the semiconductor device of the claim 1 is proposed, wherein the magnification factor value of the low magnification factor is determined taking the stage precision of the stage into consideration so that observational positioning at low magnification factor with the pattern observation device is performed, where the observation center of the specified portion is placed in an observational field of view.

According to the invention of claim 3, a navigation method for pattern observation of the semiconductor device of the claim 1or 2 is proposed, wherein the CAD graphics data describes the CAD graphic having its center on the observation center, and the offset amount is calculated from the coordinate data of the observation center of the specified portion of the image based on the low magnification factor pattern image data and the coordinate data corresponding to the center point of the CAD graphic.

According to the invention of claim 4, a navigation method for pattern observation of the semiconductor device of claim 3 is proposed, wherein the offset amount is calculated as an amount of image shift in the observation plane.

According to the invention of claim 5, a navigation method for pattern observation of the semiconductor device of the claim 1 is proposed, wherein a pattern edge is extracted based on the low magnification factor pattern image data, and the offset amount is calculated from the obtained edge data and the CAD graphics data.

According to the invention of claim 6, there is proposed a navigation device, for pattern observation of the semiconductor device for magnifying a specified pattern portion of a semiconductor device set on a stage for observation to a high magnification factor, and for positioning the observational field of view of the pattern observation device at the specified pattern portion of the semiconductor device, comprising designation means for designating the specified part, memory means for storing the CAD data corresponds to the pattern, memory means for storing the CAD data corresponds to the pattern, low magnification factor pattern image data acquisition means for acquiring the low magnification factor pattern image data of the semiconductor device by performing the observational positioning of the pattern observation device to a low magnification factor so that the observation center of the specified part is placed in an observational field of view in response to the designation means, extraction means for extracting the edge line segment data by performing the pattern edge extraction based on the low magnification factor pattern image data, means for obtaining CAD line segment data in response to the designation means and the memory means, means for calculating an offset amount between the observation center and the center of the observational field of view by comparing the CAD line segment data to the edge line segment data, and position control means for aligning the observation center with the center of the observational field of view by compensating the stage error of the stage based on the offset amount.

### BRIEF DESCRIPTION OF THE DRAWINGS

FIG. 1 is schematic configuration view of one embodiment of the semiconductor device pattern observation system according to the present invention.

FIG. 2 is flow diagram for the explanation of the operation of the semiconductor device shown in FIG. 1.

FIG. 3 is a structural view for explaining one example of the configuration of the navigation unit shown in FIG. 1.

### DETAILED DESCRIPTION OF THE PREFERRED EMBODIMENTS

The following is a detailed description, with reference to drawings, of a preferred embodiment of the present invention.

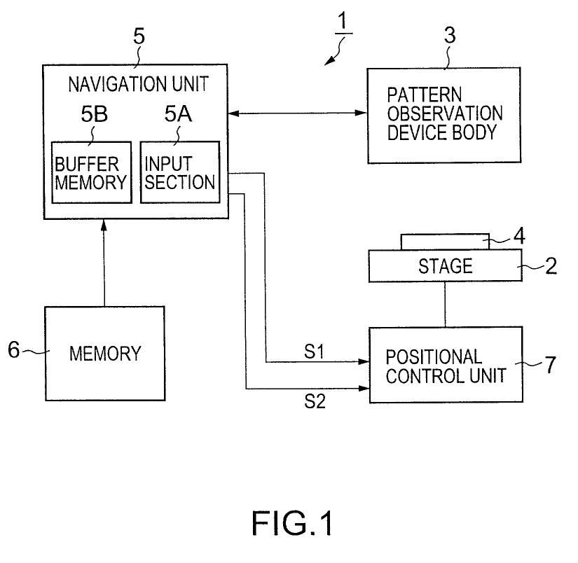

FIG. 1 is a schematic system configuration view showing an embodiment of the pattern observation system provided with a navigation unit, configured to perform navigation for pattern observation of the semiconductor device according to the method of the present invention.

In a pattern observation system1, 2 is a stage and 3 is a pattern observation device. A navigation unit 5 is arranged for magnifying the specified portion of a pattern (not shown) of the semiconductor device 4 set on the stage 2 to a high magnification factor to observe with the pattern observation device 3.

The navigation unit 5 refers to sections of CAD graphics data necessary for patterning the semiconductor device 4 previously stored in the memory 6 arranged at the outer part, then calculates the offset amount data to correct the relative position between the stage 2 and the pattern observation device 3 stage by the amount of the stage error. The position control unit 7 is operated according to the offset amount data so that the observational field of view of the pattern observation device 3 is positioned precisely at the specified portion on the semiconductor device.

The navigation unit 5 comprises a well-known computer device comprising a micro computer, in which a specified navigation program is installed. The navigation unit 5 is operated according to the program, and as a result, the auto-positioning of the observational field of view of the pattern observation device 3, which is necessary to magnify the pattern of the semiconductor device 4 to a high scale to perform observation, is performed with high precision.

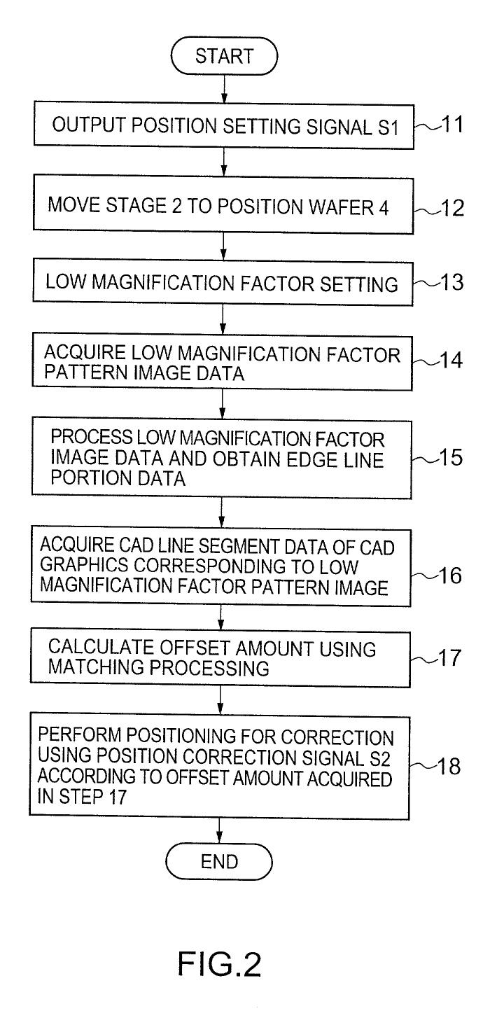

FIG. 2 is the flow diagram of the navigation program. The navigation operation of the navigation unit 5 will now be described with reference to FIG. 2 in the following.

When the desired observation pattern portion of the semiconductor device is input from the input device 5A, the position setting signal S1 is output in response to the designation of the observation portion in Step 11. In Step 12, the position control unit 7 moves the stage 2 in response to the position setting signal S1. As a result, the semiconductor device 4 is positioned with respect to the pattern observation device 3 so that the center of the observational field of view of the pattern observation device 3 is aligned with the observation center of the observation portion specified at this time.

In the next Step 13, the observation magnification factor of the pattern observation device 3 is set at an appropriate low magnification factor, so that the observation center of the specified observation portion is placed in the observational field of view of the pattern observation device 3. With regards to the low magnification factor, for example, even when predicted position setting error is predicted in the positioning of the stage 2, the magnification factor can be designated by taking stage precision of the stage 2 into consideration, so that the observation center of the observation portion is placed in the observational field of view of the pattern observation device 3.

In Step 14, according to the instruction of the navigation unit 5, the low magnification factor pattern image data is obtained by the pattern observation device 3 under the above mentioned observation condition. The obtained low magnification factor pattern image data is stored in the memory 5B in the navigation unit 5.

In Step 15, the low magnification factor pattern image data stored in the buffer memory 5B is processed by a well know method to extract its edge. As a result, edge line segment data of the observation image based on the low magnification factor pattern image data is obtained.

In the next Step 16, the CAD graphics data corresponding to the low magnification factor pattern image data obtained in Step 14 is read out from the memory 6, then stored in the buffer memory 5B. The CAD graphics data describes the CAD graphic having its center point at the observation center of the pattern observation device 3. The CAD line segment data is obtained based on the read out CAD graphics data. The CAD line segment data describes the line segment of the pattern according to the CAD graphic.

Also, in Step 17, a matching processing is performed, where the edge line segment data is compared to the CAD line segment data. As a result, the offset amount between the observation center and the center of the observational field of view of the pattern observation device 3 is calculated. The offset amount is calculated as an amount of image shift within the observation plane.

In Step 18, according to the offset amount obtained in Step 17, a position correction signal S2 is outputted to move the stage 2 to align the observation center with the center of the observational field of view of the pattern observation device 3. As a result, the observation center is aligned with the center of the observational field of view of the pattern observation device 3.

As described above, using the navigation unit 5, first, the offset amount between the observation center of the low scale pattern image and the actual center of the observational field of view of the pattern observation device 3 is calculated. Regarding the offset amount as the positioning error according to the stage precision, the stage 2 is moved by the offset amount, and therefore the observational field of view of the pattern observation device 3 can be positioned precisely at the required observation pattern portion of the semiconductor device 4. Also, each operation for positioning described above may be carried out by moving the pattern observation device 3.

Accordingly, if the precise positioning as mentioned above, using the navigation unit 5, is completed, by setting the magnification factor of the pattern observation device 3 to the desired high magnification factor, the high scale pattern image at the desired pattern portion of the semiconductor device can be obtained instantly.

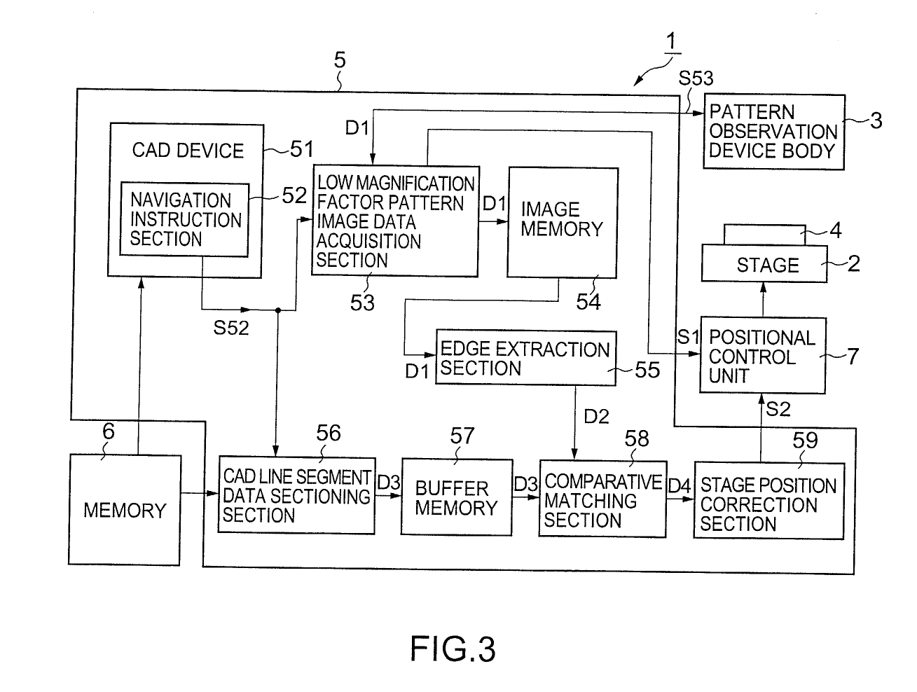

In FIG. 3, device configuration view of the pattern observation system1 shown in FIG. 1 is shown to describe the configuration of the navigation unit 5 in one of the embodiment. The same numerals are used for the sections in FIG. 3, that correspond to those in FIG. 1, and the descriptions for those sections are omitted.

As to the description of the configuration of the navigation unit 5, 51 is a CAD device, which comprises a navigation instruction section 52. 53 is a low magnification factor pattern image data acquisition section. When the observation portion is designated by the navigation instruction section 52, it responds to the outputted instruction signal S52 and outputs position setting signal S1, and then the positioning of the stage 2 described in Step 2 in FIG. 2 is carried out. On the other hand, in response to the magnification factor setting signal S53, the pattern observation device 3 is set to a low magnification factor as described in Step 13, and the low magnification factor pattern image data D1 obtained by the pattern observation device 3 is transmitted to the low magnification factor pattern image data acquisition section 53, and then stored in image memory 54. Also, at the edge extraction section 55, the edge extract processing is performed based on the low magnification factor pattern image data stored in the image memory 54, as described in Step 15 in FIG. 2, then the edge line segment data D2 is outputted.

On the other hand, in the CAD line segment data sectioning section 56, the CAD line segment data D3 corresponding to the observation portion is read out from the memory 6 in response to the instruction signal S52 from the navigation instruction section, and then stored in the buffer memory 57.

In the compare matching section 58, the edge line segment data D2 from the edge extraction section 55 and the CAD line segment data D3 from the buffer memory 57 are compared to each other, and matching processing is carried out to calculate the offset amount The calculate processing here corresponds to the processing described in Step 17 of FIG. 2. Offset amount data D4, describing the offset amount obtained by the compare matching section 58, is transferred to the stage position correction section 59. There a position correction signal S2 for moving the stage 2 is generated, so that the observation center of the low scale pattern image is aligned with the actual center of the observational field of view of the pattern observation device 3, and this signal S2 is transferred to position control unit 7.

According to the present invention, first, the pattern observation device performs observational positioning to a low magnification factor, so that the observation center of the specified pattern portion is placed in the observational field of view, and obtains the low magnification factor pattern image data in which the center of the observational position is included. The offset amount caused by the stage error is then calculated by comparing the low magnification factor pattern image data to the corresponding CAD graphics data, and the stage is moved relatively to compensate the offset amount to precisely perform positioning of the observational field of view of the pattern observation device in the specified pattern portion. Therefore the high scale pattern image of the desired position of the pattern of the semiconductor device can be obtained without manual intervention. Accordingly, the pattern observation can be automated, and pattern observation for the semiconductor device at a high magnification factor can be performed with very high efficiency without manual intervention. As a result, the operation of the observation device can be automated, and the efficiency of the semiconductor manufacturing can be improved significantly. Additionally, the observation object can be designated precisely from the CAD screen.

What is claimed is:

1. A navigation method, for magnifying a specified pattern portion of a semiconductor device set on a stage for observation to a high magnification factor, and for positioning the observational field of view of the pattern observation device at the specified pattern portion of the semiconductor device, comprising the steps of:
carrying out observational positioning of the pattern observation device to a low magnification factor so that an observation center of the specified portion is placed in an observational field of view to acquire low magnification factor pattern image data; for the semiconductor device;
calculating an offset amount between the observation center and a center of the observational field of view from the low magnification factor pattern image data and CAD graphics data corresponding to the low magnification factor pattern image data; and
performing positional control by compensating the stage error based on this offset amount data so that the observation center is aligned with the center of the observational field of view.

2. The navigation method for pattern observation of the semiconductor device of claim 1, wherein determination of the magnification factor value of the low magnification factor is carried out taking the stage precision of the stage into consideration for performing observational positioning of the pattern observation device to a low magnification factor so that the observation center of the specified portion is placed in the observational field of view.

3. The navigation method for pattern observation of the semiconductor device of claim 2, wherein the CAD graphics data describes the CAD graphics having its center on the observation center, and an offset amount is calculated from the coordinate data of the observation center of the specified portion of the image based on the low magnification factor pattern image and the coordinate data corresponds to the center point of the CAD graphic.

4. The navigation method for pattern observation of the semiconductor device of claim 3, wherein the offset amount is calculated as an amount of image shift on and within the observation plane.

5. The navigation method for pattern observation of the semiconductor device of claim 1, wherein a pattern edge is extracted based on the low magnification factor pattern image data, and the offset amount is calculated from the obtained edge data and the CAD graphics data.

6. A navigation device for pattern observation of the semiconductor device for magnifying a specified pattern portion of a semiconductor device set on a stage for observation to a high magnification factor, and for positioning the observational field of view of the pattern observation device at the specified pattern portion of the semiconductor device comprising:
designation means for designating the specified portion;
memory means for storing the CAD data corresponding to the pattern;
low magnification factor pattern image data acquisition means for acquiring low magnification factor pattern image data of the semiconductor device by performing observational positioning at a low magnification factor so that the observation center of the specified portion is placed in the observational field of view in response to the designation means;
extraction means for extracting edge line segment data by performing pattern edge extraction based on the low magnification factor pattern image data;
means for obtaining CAD line segment data corresponding to the low magnification factor pattern image data in response to the designation means and the memory means;
means for calculating an offset amount between the observation center and the center of the observational field of view by comparing the CAD line segment data to the edge Line segment data; and
position control means for aligning the observation center with the center of the observational field of view by compensating a stage error of the stage based on the offset amount.

7. The navigation method for pattern observation of the semiconductor device of claim 1, wherein the CAD graphics data describes the CAD graphics having its center on the observation center, and an offset amount is calculated from the coordinate data of the observation center of the specified portion of the image based on low magnification factor pattern image and the coordinate data corresponds to the center point of the CAD graphic.
